(19) United States
(12) Patent Application Publication
(10) Pub. No.: US 2016/0041493 A1
(43) Pub. Date: Feb. 11, 2016

(54) LIGHT EMITTING APPARATUS AND IMAGE FORMING APPARATUS

(71) Applicant: CANON KABUSHIKI KAISHA, Tokyo (JP)

(72) Inventors: Tatsuhito Goden, Machida-shi (JP); Takashi Moriyama, Yokohama-shi (JP); Norifumi Kajimoto, Tokyo (JP); Satoru Shiobara, Funabashi-shi (JP)

(21) Appl. No.: 14/817,559

(22) Filed: Aug. 4, 2015

(30) Foreign Application Priority Data
Aug. 11, 2014 (JP) 2014-163708
Apr. 27, 2015 (JP) 2015-090355

(51) Int. Cl. H01L 29/08

(52) U.S. Cl. CPC G03G 15/04036; H01L 27/3246; H01L 27/3248; H01L 27/3276

(57) ABSTRACT

A light emitting apparatus includes: a pixel circuit formed over a substrate; a partition including a plurality of openings formed over the substrate with the pixel circuit; and a plurality of pixels defined by the plurality of the openings, wherein the pixel includes a light emitting element including a lower electrode connected to the pixel circuit and an organic compound layer formed over the lower electrode, the plurality of the pixels is arranged in a line in a longitudinal direction of the substrate, the pixel circuit includes: a transistor including a gate electrode and source/drain electrodes; a first interconnection including the gate electrode; and a second interconnection including the source/drain electrodes, and the second interconnection and an interconnection formed of a same layer as the second interconnection are separated from the organic compound layer in planar view from a direction perpendicular to a main surface of the substrate.

### BACKGROUND OF THE INVENTION

1. Field of the Invention

The present invention relates to a light emitting apparatus using a light emitting element and an image forming apparatus using the light emitting apparatus. Particularly, the present invention relates to a light emitting apparatus using an organic electroluminescence element (hereinafter, called “organic EL element”) as the light emitting element and to an image forming apparatus using the light emitting apparatus.

2. Description of the Related Art

A printer with a laser scan system based on an electrophotographic technique is widely used. In a general printer with a laser scan system, a scan unit performs scanning with laser light emitted from a laser light source to perform exposure of a photoreceptor. However, reducing the size of the scan unit for scanning with laser light is difficult due to the structure of the scan unit.

Meanwhile, as an exposure system of a printer based on the electrophotographic technique, a system is studied, wherein light emitting elements are arranged in a line, and a light emitting apparatus that controls light emission of the light emitting elements performs exposure of a photoreceptor. In this system, the size of a light source unit using the light emitting apparatus can be reduced, which contributes to the downsizing of the printer. Particularly, organic EL elements allow manufacturing a high-precision, low-power-consumption light emitting apparatus, and thus the organic EL elements are favorable as light emitting elements in a light emitting apparatus for printer.

It is known that while the organic EL elements are excellent light emitting elements, moisture degrades the characteristics of the organic EL elements. Therefore, suppressing the movement of moisture to the organic EL elements is necessary to maintain the light emission performance of the organic EL elements.

Japanese Patent Application Laid-Open No. 2006-66871 discloses a head of a printer using a light emitting apparatus including organic EL elements arranged in a line.

### SUMMARY OF THE INVENTION

In the light emitting apparatus described in Japanese Patent Application Laid-Open No. 2006-66871, a partition made of a resin material is formed on electrodes to separate light emitting regions of the organic EL elements. When a resin is used for the partition, the partition obtained by patterning the resin material contains a small amount of moisture. Therefore, when a resin is used for the partition, the moisture included in the partition may move to the organic EL elements, and the elements may be degraded.

Consequently, a film, such as a silicon nitride (SiN) film, made of an inorganic material instead of a resin may be used for the partition. However, if the SiN film is formed as thick as the resin, the taper of the partition becomes large, and this is not suitable for manufacturing the organic EL elements that are thin films. Therefore, forming a thick SiN film for the partition is difficult. On the other hand, if the SiN film formed as the partition is thin, flattening the unevenness of interconnections in the light emitting regions is difficult. As a result, even if a sealing film, such as a SiN film, for suppressing the infiltration of moisture to prevent the degradation of the organic EL elements is formed on the substrate provided with the organic EL elements, a defect may be generated in the sealing film due to the unevenness of the interconnections. If a defect is generated in the sealing film, the sealing performance of the sealing film is reduced.

In the light emitting apparatus described in Japanese Patent Application Laid-Open No. 2006-66871, metal interconnections formed by the same material as source/drain electrodes of transistors are arranged around the light emitting elements. However, the interconnections are also used for power supply interconnections, and the film thickness is large. Therefore, the unevenness becomes evident, and the possibility of the generation of a defect in the sealing film is significantly high.

The present invention has been made to solve the above problem, and an object of the present invention is to provide a light emitting apparatus that can realize excellent sealing performance and maintain light emission performance of a light emitting element for a long time and an image forming apparatus using the light emitting apparatus.

An aspect of the present invention provides a light emitting apparatus including: a pixel circuit formed over a long substrate; a partition formed over the substrate provided with the pixel circuit, the partition including a plurality of openings; and a plurality of pixels defined by the plurality of the openings, wherein the pixel includes a light emitting element including a lower electrode connected to the pixel circuit and an organic compound layer formed over the lower electrode, the plurality of the pixels is arranged in a line in a longitudinal direction of the substrate, the pixel circuit includes: a transistor including a gate electrode and source/drain electrodes; a first interconnection including the gate electrode; and a second interconnection including the source/drain electrodes, and the second interconnection and an interconnection formed of a same layer as the second interconnection are separated from the organic compound layer in planar view from a direction perpendicular to a main surface of the substrate.

Another aspect of the present invention provides a light emitting apparatus including: a pixel circuit formed over a long substrate; a partition formed over the substrate provided with the pixel circuit, the partition made of an inorganic material including a plurality of openings; and a plurality of pixels defined by the partition, the pixel including a light emitting element including: a lower electrode connected to the pixel circuit; an upper electrode; and an organic compound layer arranged between the lower electrode and the upper electrode, a part of the upper electrode arranged on the partition, a data line for supplying a signal arranged adjacent to the upper electrode, wherein a distance between an end of the upper electrode and the data line in an in-plane direction is 2 μm or more.

Further features of the present invention will become apparent from the following description of exemplary embodiments with reference to the attached drawings.

### BRIEF DESCRIPTION OF THE DRAWINGS

FIG. 1 is a schematic diagram illustrating an upper surface of a light emitting apparatus according to a first embodiment of the present invention.

FIG. 2 is a planar view illustrating a configuration of a pixel region and the vicinity of the pixel region in the light emitting apparatus according to the first embodiment of the present invention.

FIG. 3 is a cross-sectional view (part 1) illustrating a configuration of the pixel region and the vicinity of the pixel region in the light emitting apparatus according to the first embodiment of the present invention, depicting a cross-sectional view along a line A-A′ of FIG. 2.

FIG. 4 is a cross-sectional view (part 2) illustrating a configuration of the pixel region and the vicinity of the pixel region in the light emitting apparatus according to the first embodiment of the present invention, depicting a cross-sectional view along a line B-B′ of FIG. 2.

FIG. 5 is a planar view illustrating a configuration of a pixel region and the vicinity of the pixel region in a light emitting apparatus according to a second embodiment of the present invention.

FIG. 6 is a planar view illustrating a configuration of a pixel region and the vicinity of the pixel region in a light emitting apparatus according to a third embodiment of the present invention.

FIG. 7 is a schematic diagram illustrating an image forming apparatus according to a fourth embodiment of the present invention.

FIG. 8 is a cross-sectional view illustrating a configuration of a pixel region and the vicinity of the pixel region in a light emitting apparatus according to a modified embodiment of the present invention.

### DESCRIPTION OF THE EMBODIMENTS

Exemplary embodiments of the present invention will now be described in detail with reference to the drawings. Well known or publicly known techniques of the technical field can be applied to the parts not particularly illustrated or described in the present specification.

### First Embodiment

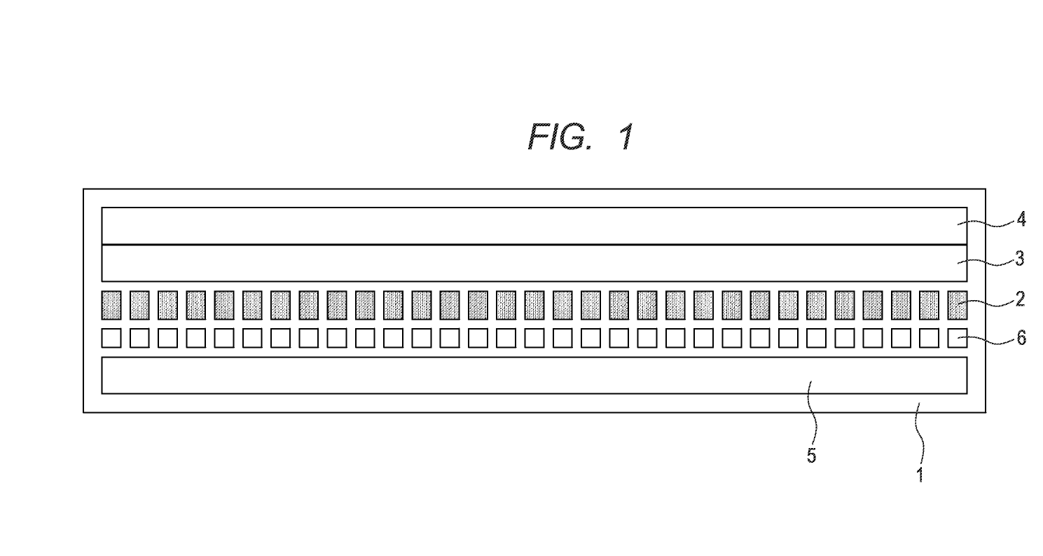

A light emitting apparatus according to a first embodiment of the present invention will be described with reference to FIGS. 1 to 4. Organic EL elements are used as light emitting elements in the light emitting apparatus according to the present embodiment, and for example, the light emitting apparatus is used as an exposure light source of an exposure head in an electrophotographic image forming apparatus.

A general configuration of the light emitting apparatus according to the present embodiment will be described first with reference to FIG. 1. FIG. 1 is a schematic diagram illustrating an upper surface of the light emitting apparatus according to the present embodiment, illustrating an arrangement closer to a substrate with respect to an organic compound layer 8 that forms organic EL elements OEL described later.

As illustrated in FIG. 1, the light emitting apparatus according to the present embodiment includes: a substrate 1 in a long rectangular planar shape; and a plurality of pixels 6 arranged and formed in a single line over the substrate 1 in a longitudinal direction of the substrate 1. Examples of the substrate 1 include, but not particularly limited to, a glass substrate, a semiconductor substrate and a plastic substrate. The length of the long rectangular substrate 1 in a transverse direction can be 10 mm or less. The length can further be 1 mm or more and 10 mm or less. As described later, each pixel 6 includes the organic EL element OEL. When an extraction system of light emission of the organic EL elements OEL is a bottom emission type, a substrate made of a translucent material is used as the substrate 1.

In the light emitting apparatus according to the present embodiment, a plurality of pixel circuits 2 corresponding to the plurality of the pixels 6 is formed over the substrate 1. The plurality of the pixel circuits is arranged in a single line in the longitudinal direction of the substrate 1. The pixel circuits 2 are configured to control the light emission of corresponding pixels 6. The line including the plurality of the pixel circuits 2 is arranged adjacent to the line including the plurality of the pixels 6. The pixel circuits 2 are formed by thin film transistors, metal interconnections and the like.

The light emitting apparatus according to the present embodiment further includes a power line 3, a scan circuit 4 and data lines 5. The power line 3, the scan circuit 4 and the data lines 5 are formed over the substrate 1.

The power line 3 supplies power supply voltage for applying drive current to the organic EL elements OEL of the pixels 6. The power line 3 is arranged in the longitudinal direction of the substrate 1 on the opposite side of the pixels 6 with respect to the plurality of the pixel circuits 2. The power line 3 is formed by a metal interconnection.

The scan circuit 4 supplies each of the pixel circuits 2 with a control signal for controlling the timing of the light emission of each of the pixels 6. The scan circuit 4 is arranged in the longitudinal direction of the substrate 1 on the opposite side of the pixel circuits 2 with respect to the power line 3. The scan circuit 4 is formed by a film transistor, a metal interconnection and the like.

The data lines 5 supply the pixels 6 with data signals indicating light emission or non-emission of the pixels 6. The data lines 5 are arranged in the longitudinal direction of the substrate 1 on the opposite side of the pixel circuits 2 with respect to the plurality of the pixels 6. The plurality of the data lines 5 correspond to the plurality of the pixels 6. The data lines 5 are formed by metal interconnections. The distance between a part of the plurality of the data lines 5 closest to the pixels 6 and an end of an upper electrode 11 described later in an in-plane direction may be 2 μm or more. When the distance is 2 μm or more, the capacitance generated between the data lines 5 and an upper electrode 11 can be reduced.

As described, in the light emitting apparatus according to the present embodiment, the plurality of the pixel circuits 2, the power line 3 and the scan circuit 4 are sequentially arranged toward the edge of the substrate 1, on a side of the plurality of the pixels 6 arranged in the longitudinal direction of the substrate 1. The data lines 5 are arranged on the other side of the plurality of the pixels 6 arranged in the longitudinal direction of the substrate 1.

Thus, the light emitting apparatus according to the present embodiment has an elongated shape in which the circuits and the interconnections are arranged on both sides of the plurality of the pixels 6 arranged in a line in the longitudinal direction of the substrate 1 in a long planar shape.

The light emitting apparatus according to the present embodiment controls the light emission of the plurality of the pixels 6 through the control signals appropriately input from a drive circuit including the scan circuit 4 corresponding to the pixels. The light emission can be used as exposure light for exposure on a photoreceptor, thereby constructing an apparatus or a device, such as an image forming apparatus like an electrophotographic printer.

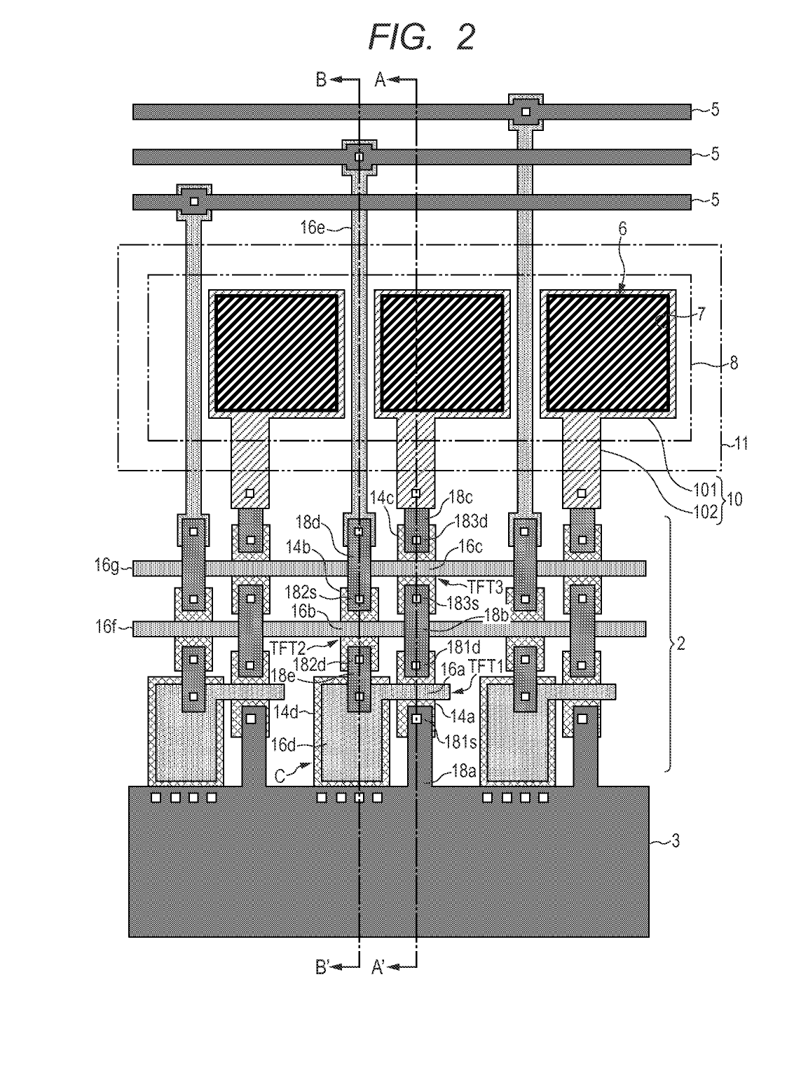

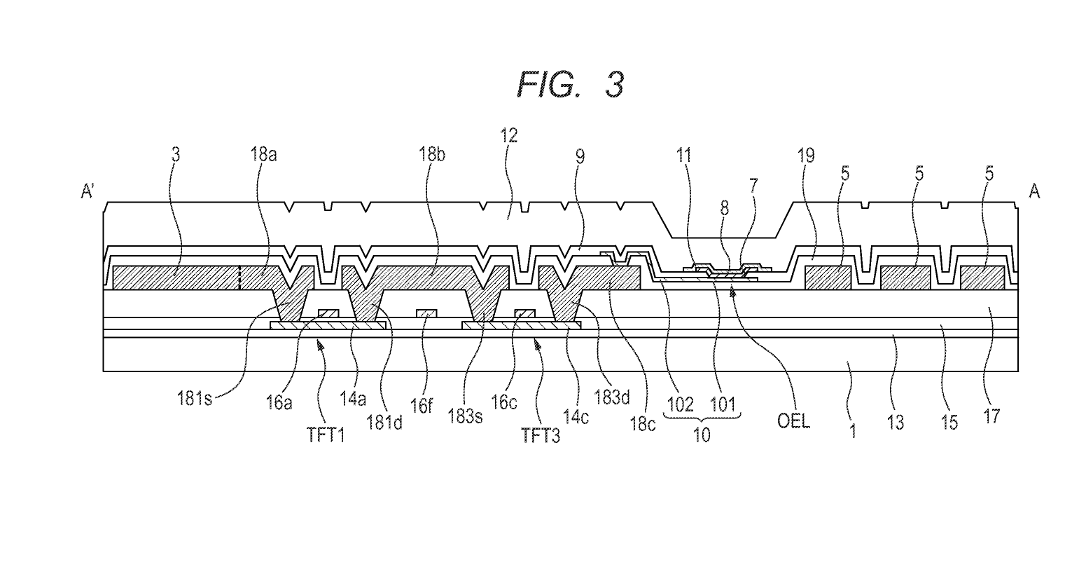

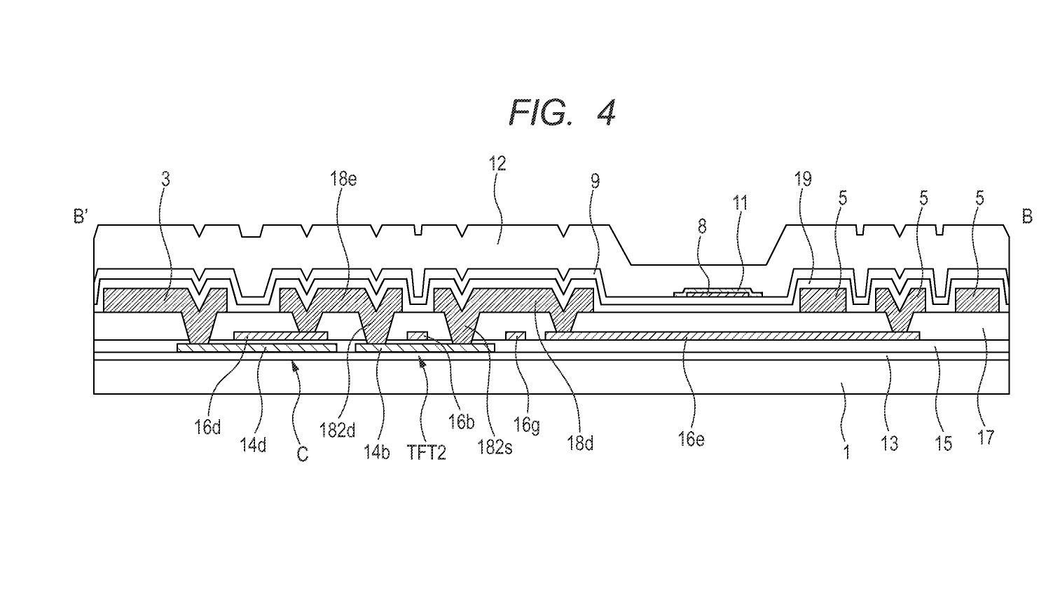

Next, a configuration of a pixel region provided with the pixels 6 and the vicinity of the pixel region in the light emitting apparatus according to the present embodiment will be described with reference to FIGS. 2 to 4. FIG. 2 is a planar view illustrating the configuration of the pixel region and the vicinity of the pixel region in the light emitting apparatus according to the present embodiment. FIGS. 3 and 4 are cross-sectional views illustrating the configuration of the pixel region and the vicinity of the pixel region in the light emitting apparatus according to the present embodiment. FIG. 3 is a cross-sectional view along a line A-A′ in FIG. 2. FIG. 4 is a cross-sectional view along a line B-B′ in FIG. 2.

As illustrated in FIGS. 3 and 4, an undercoat layer 13 made of, for example, a silicon oxide film or a silicon nitride film is formed on the substrate 1 such as a glass substrate.

Channel layers 14a, 14b and 14c and an electrode layer 14d made of, for example, a polysilicon film or an amorphous silicon film are formed on the undercoat layer 13 in the region provided with the pixel circuit 2. The channel layers 14a, 14b and 14c serve as channel layers of thin film transistors TFT1, TFT2 and TFT3 described later included in the pixel circuits 2, respectively. The electrode layer 14d serves as one of capacitance electrodes of a holding capacitance C described later included in the pixel circuit 2. The channel layers 14a, 14b and 14c and the electrode layer 14d are formed of the same layer.

A gate insulating film 15 made of, for example, a silicon oxide film or a silicon nitride film is formed on the channel layers 14a, 14b and 14c and the electrode layer 14d. The gate insulating film 15 is also formed on the undercoat layer 13 not provided with the channel layers 14a, 14b and 14c and the electrode layer 14d, thereby also functioning as an interlayer insulating layer.

Gate electrodes 16a, 16b and 16c made of, for example, aluminum, copper, chromium or an alloy of these are formed on the channel layers 14a, 14b and 14c, respectively, with the gate insulating film 15 therebetween. The gate electrodes 16a, 16b and 16c serve as gate electrodes of the thin film transistors TFT1, TFT2 and TFT3, respectively.

An electrode layer 16d is formed on the electrode layer 14 with the gate insulating film 15 therebetween. The electrode layer 16d is integrated with the gate electrode 16a. The electrode layer 16d serves as the other capacitance electrode of the holding capacitance C. The gate insulating film 15 between the electrode layer 14d and the electrode layer 16d functions as a dielectric of the holding capacitance C. The gate electrodes 16a, 16b and 16c and the electrode layer 16d are formed of the same layer.

A relay interconnection 16e is formed on the gate insulating film 15. The relay interconnection 16e is made of, for example, aluminum, copper, chromium or an alloy of these formed of the same layer as the gate electrodes 16a, 16b and 16c.

An interlayer insulating layer 17 made of, for example, a silicon oxide film is formed on the gate insulating film 15 provided with the gate electrodes 16a, 16b and 16c, the electrode layer 16d, and the relay interconnection 16e.

A metal interconnection 18a including a source electrode 181s of the thin film transistor TFT1 is formed on the interlayer insulating layer 17. The source electrode 181s is connected to one end of the channel layer 14a through a contact hole formed in the interlayer insulating layer 17 and the gate insulating film 15. The source electrode 181s is integrated with the metal interconnection 18a. The metal interconnection 18a is integrated with the power line 3.

A metal interconnection 18b including a drain electrode 181d of the thin film transistor TFT1 and a source electrode 183s of the thin film transistor TFT3 is formed on the interlayer insulating layer 17. The drain electrode 181d is connected to the other end of the channel layer 14a through a contact hole formed in the interlayer insulating layer 17 and the gate insulating film 15. The source electrode 183s is connected to one end of the channel layer 14c through a contact hole formed in the interlayer insulating layer 17 and the gate insulating film 15. The drain electrode 181d and the source electrode 183s are integrated with the metal interconnection 18b.

A metal interconnection 18c including a drain electrode 183d of the thin film transistor TFT3 is formed on the interlayer insulating layer 17. The drain electrode 183d is connected to the other end of the channel layer 14c through a contact hole formed in the interlayer insulating layer 17 and the gate insulating film 15. The drain electrode 83d is integrated with the metal interconnection 18c.

A metal interconnection 18d including a source electrode 182s of the thin film transistor TFT2 is formed on the interlayer insulating layer 17. The source electrode 182s is connected to one end of the channel layer 14b through a contact hole formed in the interlayer insulating layer 17 and the gate insulating film 15. The source electrode 182s is integrated with the metal interconnection 18d. The metal interconnection 18d is connected to one end of the relay interconnection 16e through a contact hole formed in the interlayer insulating layer 17.

A metal interconnection 18e including a drain electrode 182d of the think film transistor TFT2 is formed on the interlayer insulating layer 17. The drain electrode 182d is connected to the other end of the channel layer 14b through a contact hole formed in the interlayer insulating layer 17 and the gate insulating film 15. The drain electrode 182d is integrated with the metal interconnection 18e. The metal interconnection 18e is connected to the electrode layer 16d through a contact hole formed in the interlayer insulating layer 17.

Thus, the thin film transistor TFT1 including the gate electrode 16a and the source/drain electrodes 181s and 181d is formed in the pixel circuit 2. The thin film transistor TFT2 including the gate electrode 16b and the source/drain electrodes 182s and 182d is also formed. The thin film transistor TFT3 including the gate electrode 16c and the source/drain electrodes 183s and 183d is also formed. The holding capacitance C including the electrode layer 14d and the electrode layer 16d is also formed.

The power line 3 is formed on the interlayer insulating layer 17. The power line 3 is connected to the electrode layer 14d through a contact hole formed in the interlayer insulating layer 17 and the gate insulating film 15. The power line 3 can be formed by a metal interconnection for the flow of current supplied to the pixel 6 when the organic EL element OEL emits light, and a low-resistance material, such as aluminum, an aluminum alloy and copper, is used. The thickness of the power line 3 is, for example, 300 nm to 1500 nm, and the thickness can be about 900 nm.

The plurality of the data lines 5 corresponding to the plurality of the sets of the pixel 6 and the pixel circuit 2 is formed on the interlayer insulating layer 17. The data line 5 is connected to the other end of the relay interconnection 16e connected to the corresponding pixel circuit 2, through a contact hole formed in the interlayer insulating layer 17. The thickness of the data line 5 may be 300 nm or more and 1500 nm or less, and the thickness can be 900 nm.

In FIGS. 3 and 4, the metal interconnection 18a, 18b, 18c, 18d and 18e, the power line 3, and the data lines 5 may be formed by the same material or different materials. Hereinafter, the metal interconnection 18a, 18b, 18c, 18d and 18e and the power line 3 will be collectively called and written as “metal interconnection 18” as necessary.

The data lines 5 may not necessarily be formed of the same layer as the metal interconnection 18 as illustrated in FIGS. 3 and 4 and may be arranged on a partition layer 9 described later included in the light emitting apparatus.

A passivation layer 19 made of, for example, a silicon nitride film is formed on the interlayer insulating layer 17 provided with the metal interconnection 18 as described above, and the passivation layer 19 covers the metal interconnection 18 and the data lines 5. The film thickness of the passivation layer 19 is, for example, 100 nm to 500 nm, and the film thickness can be about 300 nm.

For each of the pixels 6, a lower electrode 10 of the organic EL element OEL is formed on the passivation layer 19. Although not particularly limited, the lower electrode 10 can be appropriately selected according to, for example, the extraction system of the light emission of the organic EL element OEL. For example, a transparent electrode, such as an ITO (indium tin oxide) film, is used for the lower electrode 10 when the extraction system of the light emission of the organic EL element OEL is a bottom emission type, and a reflective electrode, such as an aluminum film, is used for the lower electrode 10 when the extraction system is a top emission type. The organic EL element OEL may be either one of the bottom emission type and the top emission type.

The lower electrode 10 includes a main body portion 101 in a predetermined planar shape and an interconnection portion 102 that functions as an interconnection connected to the pixel circuit 2. The main body portion 101 has a planar shape according to the planar shape of the pixel 6, and for example, the main body portion 101 has a rectangular planar shape such as a square. The interconnection portion 102 extends toward the pixel circuit 2 from the main body portion 101. The interconnection portion 102 is connected to the metal interconnection 18c through a contact hole formed in the passivation layer 19.

The partition layer 9 that functions as a partition is formed on the passivation layer 19 provided with the lower electrode 10. An opening 7 that defines the pixel 6 is formed in a region on the main body portion 101 of the lower electrode 10 in the partition layer 9, and the opening 7 of the partition layer 9 partitions the light emitting region of the pixel 6. The opening 7 reaches the main body portion 101 of the lower electrode 10. The opening 7 has a planar shape according to the planar shape of the pixel 6, and for example, the opening 7 has a rectangular planar shape such as a square.

If a resin, such as an acrylic resin and a polyimide resin, that is an organic material is used as a material of the partition layer 9, the partition layer 9 obtained by patterning the resin and thus forming an opening contains a small amount of moisture. The small amount of moisture is derived from, for example, a wet process for patterning the resin. In this way, if the partition layer 9 contains moisture, the moisture in the partition layer 9 may move to the organic EL element OEL, and the organic EL element OEL may be degraded.

On the other hand, instead of an organic material, a film made of an inorganic material with a low water permeability is used for the partition layer 9 in the light emitting apparatus according to the present embodiment. Specifically, an example of the film made of an inorganic material with a low water permeability includes a film made of silicon nitride (SiN), silicon oxide (SiO), a mixture of these, aluminum oxide or a mixture of aluminum oxide. The amount of moisture included in the partition layer 9 made of an inorganic material, such as a silicon nitride film and a silicon oxide film, is significantly lower than that of the partition layer 9 made of a resin material, i.e. an organic material. Therefore, the light emitting apparatus according to the present embodiment can significantly suppress the degradation of the organic EL element OEL caused by the moisture from the partition layer 9. The partition layer 9 made of an inorganic material is formed thinner than when an organic material such as a resin is used. The film thickness of the partition layer 9 is, for example, 50 nm to 400 nm, and the film thickness can be about 200 nm.

The organic compound layer 8 in a band shape is formed on the lower electrodes 10 in the openings 7 and on the partition layer 9, in the longitudinal direction of the substrate 1. The organic compound layer 8 is formed in a band shape along the plurality of the pixels 6 arranged in a single line (see FIG. 2) and is common to the organic EL elements OEL in the plurality of the pixels 6. The structure and the material of the organic compound layer 8 are not particularly limited. For example, the organic compound layer 8 can have a layered structure including a light emitting layer placed between an electron transport layer and a hole transport layer, and the material of each layer can also be appropriately selected.

The upper electrode 11 is formed on the organic compound layer 8 and on the partition layer 9. The upper electrode 11 is formed in a band shape in the longitudinal direction of the substrate 1 so as to cover the band-like organic compound layer 8 (see FIG. 2), and the upper electrode 11 is common to the organic EL elements OEL in the plurality of the pixels 6. Although not particularly limited, the upper electrode 11 can be appropriately selected according to, for example, the extraction system of the light emission of the organic EL elements OEL. For example, a reflective electrode made of aluminum is used for the upper electrode 11 when the extraction system of the light emission of the organic EL elements OEL is a bottom emission type. A transparent electrode, such as an oxide made of ITO and a thin metal film made of silver, magnesium or an alloy of silver and magnesium, is used for the upper electrode 11 when the extraction system of the light emission of the organic EL elements OEL is a top emission type.

Thus, the organic EL element OEL including the lower electrode 10, the organic compound layer 8 and the upper electrode 11 is formed as a light emitting element included in each of the pixels 6. The organic compound layer 8 and the upper electrode 11 may be separated for each of the pixels 6. In the organic EL element OEL, the organic compound layer 8 in the opening 7 emits light when a current flows between the lower electrode 10 and the upper electrode 11.

A sealing film 12 made of an inorganic material is formed on the upper electrode 11 and on the partition layer 9. The sealing film 12 is made of an inorganic material with a low water permeability. Specifically, examples of the inorganic material include silicon nitride (SiN), silicon oxide (SiO), a mixture of these, aluminum oxide and a mixture of aluminum oxide and another inorganic material. The sealing film 12 is formed up to the end of the substrate 1. The sealing film 12 thus formed cuts off the organic EL element OEL from the external atmosphere including moisture and oxygen. A plasma CVD method can be used as a method of forming the sealing film 12. The translucency is not required for the sealing film 12 when the extraction system of the light emission of the organic EL element OEL is a bottom emission type. On the other hand, the sealing film 12 needs to be translucent to extract the light emission toward the sealing film 12 when the extraction system of the light emission of the organic EL element OEL is a top emission type, and the sealing film 12 is formed by a translucent material.

As illustrated in FIG. 2, the pixel circuit 2 includes the thin film transistors TFT1, TFT2 and TFT3 and the holding capacitance C.

The source electrode 181s of the thin film transistor TFT1 is connected to the power line 3 through the metal interconnection 18a. The source electrode 181s, the metal interconnection 18a and the power line 3 are integrally formed of the same layer.

The gate electrode 16a of the thin film transistor TFT1 is connected to the electrode layer 16d of the holding capacitance C. The gate electrode 16a and the electrode layer 16d are integrally formed of the same layer. The gate electrode 16a is further connected to the drain electrode 182d of the thin film transistor TFT2 through the electrode layer 16d and the metal interconnection 18e. The metal interconnection 18e and the drain electrode 182d are integrally formed of the same layer.

The drain electrode 181d of the thin film transistor TFT1 is connected to the source electrode 183s of the thin film transistor TFT3 through the metal interconnection 18b. The drain electrode 181d, the metal interconnection 18b and the source electrode 183s are integrally formed of the same layer.

The source electrode 182s of the thin film transistor TFT2 is connected to the data line 5 through the metal interconnection 18d and the relay interconnection 16e. The source electrode 182s and the metal interconnection 18d are integrally formed of the same layer. On the other hand, the relay interconnection 16e is separately formed of a different layer from the source electrode 182s and the metal interconnection 18d.

The drain electrode 183d of the thin film transistor TFT3 is connected to the interconnection portion 102 of the lower electrode 10 in the organic EL element OEL through the metal interconnection 18c. The drain electrode 183d and the metal interconnection 18c are integrally formed of the same layer. On the other hand, the lower electrode 10 including the interconnection portion 102 is separately formed of a different layer from the drain electrode 183d and the metal interconnection 18c.

The gate electrode 16b of the thin film transistor TFT2 is connected to a first control line 16f. The gate electrode 16b and the first control line 16f are integrally formed of the same layer. The plurality of the gate electrodes 16b formed in the plurality of the pixel circuits 2 is connected to the common first control line 16f.

The gate electrode 16c of the thin film transistor TFT3 is connected to a second control line 16g. The gate electrode 16c and the second control line 16g are integrally formed of the same layer. The plurality of the gate electrodes 16c formed in the plurality of the pixel circuits 2 is connected to the common second control line 16g.

Thus, the pixel circuit 2 arranged in each pixel 6 is formed. The light emitting apparatus according to the present embodiment including the pixel circuit 2 is driven, for example, as follows to control the light emission of the plurality of the pixels 6.

Before the light emission, the thin film transistors TFT2 and TFT3 in each pixel circuit 2 are off. In this state, the drive voltage of the organic EL element OEL of each pixel 6 is 0 V.

In a writing period, a control signal is input to the first control line 16f, and the control signal turns on the thin film transistor TFT2 in each pixel circuit 2. Subsequently, a data signal indicating one of light emission and non-emission of the pixel 6 is input to each data line 5.

The data signal input to each data line 5 is input to the gate electrode 16a of the thin film transistor TFT1 through the thin film transistor TFT2 that is turned on, and the data signal is input and held in the holding capacitance C. In this way, the data signal indicating one of light emission and non-emission of the pixel 6 is written in the gate electrode 16a and the holding capacitance C in the writing period.

Then, the writing period is switched to a light emitting period. The control signal input to the first control line 16f is turned off, and the thin film transistor TFT2 in each pixel circuit 2 is turned off. A control signal is input to the second control line 16g, and the control signal turns on the thin film transistor TFT3 in each pixel circuit 2. In this case, the thin film transistor TFT1 is turned on if the data signal indicating light emission is written in the gate electrode 16a and the corresponding holding capacitance C in the writing period and is turned off if the data signal indicating non-emission is written.

In the pixel 6 in which the thin film transistor TFT1 of the corresponding pixel circuit 2 is turned on, the power line 3 applies a drive voltage to the organic EL element OEL, and a drive current flows. As a result, the organic EL element OEL emits light. On the other hand, in the pixel 6 in which the thin film transistor TFT1 of the corresponding pixel circuit 2 is turned off, the drive voltage is not applied to the organic EL element OEL, and the organic EL element OEL does not emit light.

When the light emitting period is finished, the control signal input to the second control line 16g is turned off, and the thin film transistor TFT3 is turned off.

In this way, the writing period and the light emitting period are switched to control the light emission of the plurality of the pixels 6.

Although the source electrodes and the drain electrodes of the thin film transistors TFT1, TFT2 and TFT3 are distinguished for the convenience of the description, the description of the source electrodes and the description of the drain electrodes may be opposite. The configuration of the pixel circuit 2 is not limited to the configuration of the present embodiment as long as the circuit configuration can control the drive current applied to the organic EL element OEL by inputting the data signal and the control signal.

In the light emitting apparatus according to the present embodiment, the metal interconnection 18a, 18b, 18c, 18d and 18e, the power line 3, and the data lines 5 are not formed below the organic compound layer 8 as illustrated in FIGS. 2 to 4. The metal interconnection 18a, 18b, 18c, 18d and 18e and the power line 3 will be collectively written as “metal interconnection 18” as necessary. The other interconnection formed of the same layer as the metal interconnection 18 is not formed below the organic compound layer 8, either.

Specifically, only the interconnection portion 102 extending from the main body portion 101 of the lower electrode 10 is formed as interconnection under the organic compound layer 8 in the cross section structure illustrated in FIG. 3. The interconnection portion 102 is connected to the metal interconnection 18c through a contact hole formed in the passivation layer 19, in a region without the formation of the organic compound layer 8. Thus, the interconnection portion 102 of the lower electrode 10 is connected to the drain electrode 183d of the thin film transistor TFT3 through the metal interconnection 18c.

On the other hand, in the cross section structure illustrated in FIG. 4, the data line 5 is connected to the relay interconnection 16e formed of a layer of the same material as the gate electrodes 16a, 16b and 16c through a contact hole. The relay interconnection 16e is formed in the width direction of the substrate 1 so as to pass below the organic compound layer 8. The metal interconnection 18d is connected to an end of the relay interconnection 16e closer to the pixel circuit 2, through a contact hole. Thus, the data line is connected to the source electrode 182s of the thin film transistor TFT2 through the relay interconnection 16e and the metal interconnection 18d. The relay interconnection 16e is arranged not to overlap the lower electrode 10 and the interconnection portion 102 in planar view from the direction perpendicular to the main surface of the substrate 1.

Thus, the light emitting apparatus according to the present embodiment has an interconnection layout in which the metal wiring 18 and the data line 5 are separated from the organic compound layer 8 in planar view from the direction perpendicular to the main surface of the substrate 1 as illustrated in FIG. 2.

The gate electrodes 16a, 16b and 16c, the relay interconnection 16e, the first control line 16f and the second control line 16g formed of the same layer as the gate electrodes 16a, 16b and 16c, and the lower electrode including the interconnection portion 102 have relatively small film thicknesses. Therefore, the unevenness caused by the interconnections is relatively small. The film thicknesses of the gate electrodes 16a, 16b and 16c, the relay interconnection 16e, the first control line 16f and the second control line 16g are, for example, 100 nm to 200 nm, and the film thicknesses can be about 150 nm. The film thickness of the lower electrode 10 is, for example, 50 nm to 100 nm, and the film thickness can be about 80 nm.

Meanwhile, the film thicknesses of the metal interconnection 18 and the data lines 5 are larger than those of the gate electrodes 16a, 16b and 16c and the lower electrode 10. The film thicknesses of the metal interconnection 18 and the data line 5 are, for example, 300 nm to 1500 nm. If relatively thick metal interconnection 18 or data lines 5 are formed below the organic compound layer 8, the unevenness caused by the metal interconnection 18 or the data lines 5 may be inconvenient. More specifically, even if the metal interconnection 18 or the data lines 5 are covered by the passivation layer 19 and the partition layer 9, the unevenness caused by the metal interconnection 18 or the data lines 5 remains in an upper layer part above the organic compound layer 8. Particularly, the partition layer 9 made of an inorganic material, such as a silicon nitride film, can be formed thinner than a partition layer made of a resin material. Therefore, when the partition layer 9 made of an inorganic material is used, the unevenness prominently remains in the upper layer part compared to when the partition layer is made of a resin material. When the sealing film 12 is formed with the unevenness in the upper layer part, a defect may be generated in the sealing film 12 due to the unevenness. Moisture and oxygen may enter from the outside, and the organic compound layer 8 may be degraded.

As described, the light emitting apparatus according to the present embodiment has the interconnection layout in which the metal interconnection 18, the interconnection formed of the same layer as the metal interconnection 18, and the data lines 5 are separated from the organic compound layer 8 in planar view from the direction perpendicular to the main surface of the substrate 1. The metal interconnection 18, the other interconnection formed of the same layer as the metal interconnection 18, and the data lines 5 are not formed below the organic compound layer 8. Therefore, the sealing film 12 formed above the organic compound layer 8 is formed on a more flat foundation even if the partition layer 9 made of an inorganic material is used, and the sealing film 12 is less likely to be affected by the unevenness of the interconnections. This can suppress the generation of a defect in the sealing film 12. Therefore, the propagation of moisture and oxygen from the external atmosphere to the organic compound layer 8 is difficult, and the degradation of the organic EL element OEL caused by moisture and oxygen can be more surely suppressed.

Distances d2 and d3 can be 2 μm or more, wherein d2 is a distance between a part of the metal interconnection 18 closest to the pixel 6 and an end of the upper electrode 11, and d3 is a distance between a part of the data line 5 closest to the pixel 6 and the end of the upper electrode 11. The distances d2 and d3 are distances in an in-plane direction parallel to the main surface of the substrate 1. This is because the water permeation speed in the in-plane direction of the substrate tends to increase in a bonded interface between different types of films, a film with a low water permeability and a film such as the upper electrode 11 and the organic compound layer 8. Therefore, the organic compound layer 8 can be sealed by forming an interface between the partition layer 9 and the sealing film 12 that are films made of inorganic materials with low water permeability. When the distances d2 and d3 are 2 μm or more, the flatness around the organic compound layer 8 and the upper electrode 11 can be secured, and the interface between the partition layer 9 and the sealing film 12 can be favorably formed. As described, the upper electrode 11 can cover the organic compound layer 8 with the highest water permeation speed in the in-plane direction of the substrate. Based on these, the infiltration of moisture and oxygen from the external atmosphere to the organic compound layer 8 can be blocked, and the degradation of the organic EL element OEL caused by moisture and oxygen can be more surely suppressed. However, the distances d2 and d3 can be designed by considering the margin of positional accuracy of a deposition apparatus or a lithography apparatus, and the distances d2 and d3 can usually be between 50 μm and 200 μm. When the distances d2 and d3 are 2 μm or more, the parasitic capacitance can be suppressed.

The interconnection portion 102 of the lower electrode 10 and the relay interconnection 16e are formed as interconnections below the organic compound layer 8, and the lower electrode 10 including the interconnection portion 102 and the relay interconnection 16e have relatively small thicknesses as described above. Therefore, the sealing film 12 on the organic compound layer 8 is less affected by the unevenness of the interconnection portion 102 and the relay interconnection 16e.

According to the present embodiment, as described above, the unevenness caused by the interconnections in the region provided with the organic EL element OEL can be reduced, and the reduction in the sealing performance of the sealing film 12 can be suppressed. Therefore, according to the present embodiment, excellent sealing performance can be realized. Thus, the degradation of the organic EL element OEL can be suppressed, and the light emission performance of the organic EL element OEL can be maintained for a long time. The distance d 3 in the in-plane direction between the end of the upper electrode 11 and the data line 5 that supplies the signal is 2 μm or more, and the parasitic capacitance can be suppressed. According to the present embodiment, the reliability of the light emitting apparatus using the organic EL element OEL can be improved. The lifetime can be prolonged, and a light emitting apparatus with an excellent drive responsiveness can be realized.

Next, a manufacturing method of the light emitting apparatus according to the present embodiment will be described. Although the metal interconnection 18 and the data lines 5 are formed of the same layer here for example, the metal interconnection 18 and the data lines 5 may be formed of different layers.

For example, the undercoat layer 13 made of, for example, a silicon oxide film or a silicon nitride film is formed on the substrate 1, such as a glass substrate, by a plasma CVD method.

A semiconductor layer made of, for example, a polysilicon film or an amorphous silicon film is formed on the undercoat layer 13, and the semiconductor layer is patterned by, for example, lithography and etching. As a result, the channel layers 14a, 14b and 14c and the electrode layer 14d are formed of the same semiconductor layer.

The gate insulating film 15 made of, for example, a silicon oxide film or a silicon nitride film, is formed on the undercoat layer 13 provided with the channel layer 14a and the like by, for example, the plasma CVD method.

A conductive film made of, for example, aluminum, copper, chromium or an alloy of these is formed on the gate insulating film 15, and the conductive film is patterned by, for example, lithography and etching. As a result, the gate electrodes 16a, 16b and 16c, the electrode layer 16d, and the relay interconnection 16e are formed of the same conductive film. Subsequently, the source/drain regions of the channel layers 14a, 14b and 14c and the electrode layer 14d are appropriately doped with impurities.

The interlayer insulating layer 17 made of, for example, a silicon oxide film, is formed on the gate insulating film 15 provided with the gate electrodes 16a and the like by, for example, the plasma CVD method.

The contact holes are formed in the interlayer insulating layer 17 and the gate insulating film 15 by, for example, lithography and etching. The contact holes formed here include two contact holes reaching one end and the other end of the channel layer 14a, two contact holes reaching one end and the other end of the channel layer 14b, and two contact holes reaching one end and the other end of the channel layer 14c. The contact holes also include a contact hole reaching the electrode layer 14d. The contact holes also include two contact holes reaching one end and the other end of the relay interconnection 16e.

A metal film made of aluminum, an aluminum alloy or copper is formed on the interlayer insulating layer 17 provided with the contact holes by, for example, a deposition method or a sputtering method. The metal film is patterned by, for example, lithography and etching. As a result, the metal interconnections 18a, 18b, 18c, 18d and 18e, the power line 3, and the data lines 5 are formed of the same metal film.

The metal interconnection 18a includes the source electrode 181s integrated with the metal interconnection 18a, and the metal interconnection 18a is also integrated with the power line 3. The source electrode 181s is connected to one end of the channel layer 14a through the contact hole. The power line 3 is connected to the electrode layer 14d through the contact hole.

The metal interconnection 18b includes the drain electrode 181d and the source electrode 183s integrated with the metal interconnection 18b. The drain electrode 181d is connected to the other end of the channel layer 14a through the contact hole. The source electrode 183s is connected to one end of the channel layer 14c through the contact hole.

The metal interconnection 18c includes the drain electrode 183d integrated with the metal interconnection 18c. The drain electrode 183d is connected to the other end of the channel layer 14c through the contact hole.

The metal interconnection 18d includes the source electrode 182s integrated with the metal interconnection 18d. The source electrode 182s is connected to one end of the channel layer 14b through the contact hole. The metal interconnection 18d is connected to one end of the relay interconnection 16e through the contact hole.

The metal interconnection 18e includes the drain electrode 182d integrated with the metal interconnection 18e. The drain electrode 182d is connected to the other end of the channel layer 14b through the contact hole. The metal interconnection 18e is connected to the electrode layer 16d through the contact hole.

The metal interconnection 18a, 18b, 18c, 18d and 18e, the power line 3, and the data lines 5 are separated from a formation planned region of the organic compound layer 8 so as not to overlap the formation planned region of the organic compound layer 8 in planar view from the direction perpendicular to the main surface of the substrate 1.

The passivation layer 19 made of, for example, a silicon nitride film is formed on the interlayer insulating layer 17 provided with the metal interconnection 18a and the like by, for example, the plasma CVD method.

A contact hole reaching the metal interconnection 18c is formed in the passivation layer 19 by, for example, lithography and etching.

A conductive film is formed on the passivation layer 19 provided with the contact hole by, for example, the CVD method or the sputtering method, and the conductive film is patterned by, for example, lithography and etching. In this way, a plurality of lower electrodes 10 made of conductive films is formed in association with the plurality of the pixels 6. The main body portion 101 in a rectangular planar shape, such as a square, as well as the interconnection portion 102 connected to the metal interconnection 18c through the contact hole are formed in the lower electrode 10. For the material of the conductive film of the lower electrode 10, a transparent electrode material or a reflective electrode material can be appropriately selected according to the extraction system of the light emission of the organic EL element OEL.

The partition layer 9 made of a film of an inorganic material, such as a silicon nitride film, is formed on the passivation layer 19 provided with the lower electrodes 10 by, for example, the plasma CVD method.

A plurality of openings 7 for exposing the lower electrodes 10 is formed in the partition layer 9 by, for example, lithography and etching. The openings 7 formed in the partition layer 9 define the pixels 6.

The organic compound layer 8 is formed by, for example, vacuum deposition of a low-molecular material using a shadow mask, in a band-like region in the longitudinal direction of the substrate 1 including the openings 7 on the partition layer 9. Although the method of forming the organic compound layer 8 is not particularly limited, an example of a favorable method includes a formation method based on vacuum deposition of a low-molecular material. In this case, the shadow mask is used to determine the region for forming the organic compound layer 8. In the organic compound layer 8, a hole transport layer and an electron transport layer are appropriately laminated along with a light emitting layer including a light emitting material. In the vacuum deposition using the shadow mask, a support can be installed on the substrate, and the support and the mask can come into contact with each other. A method of applying and drying an organic compound can also be used as a method of forming the organic compound layer 8. The method of application can be a publicly known method, and examples of the method include an inkjet method, a spin coating method and a dipping method.

A conductive film is formed on the partition layer 9 provided with the organic compound layer 8 by, for example, the CVD method or the sputtering method, and the conductive film is patterned by, for example, lithography and etching. In this way, the upper electrode 11 made of the conductive film is formed in a band-like region in the longitudinal direction of the substrate 1 including the organic compound layer 8 on the partition layer 9. For the material of the conductive film of the upper electrode 11, a reflective electrode material or a transparent electrode material can be appropriately selected according to the extraction system of the light emission of the organic EL elements OEL.

The sealing film 12 made of, for example, a silicon nitride film, is formed on the partition layer 9 provided with the upper electrode 11 by, for example, the plasma CVD method or the sputtering method.

In this way, the light emitting apparatus according to the present embodiment is manufactured.

### Second Embodiment

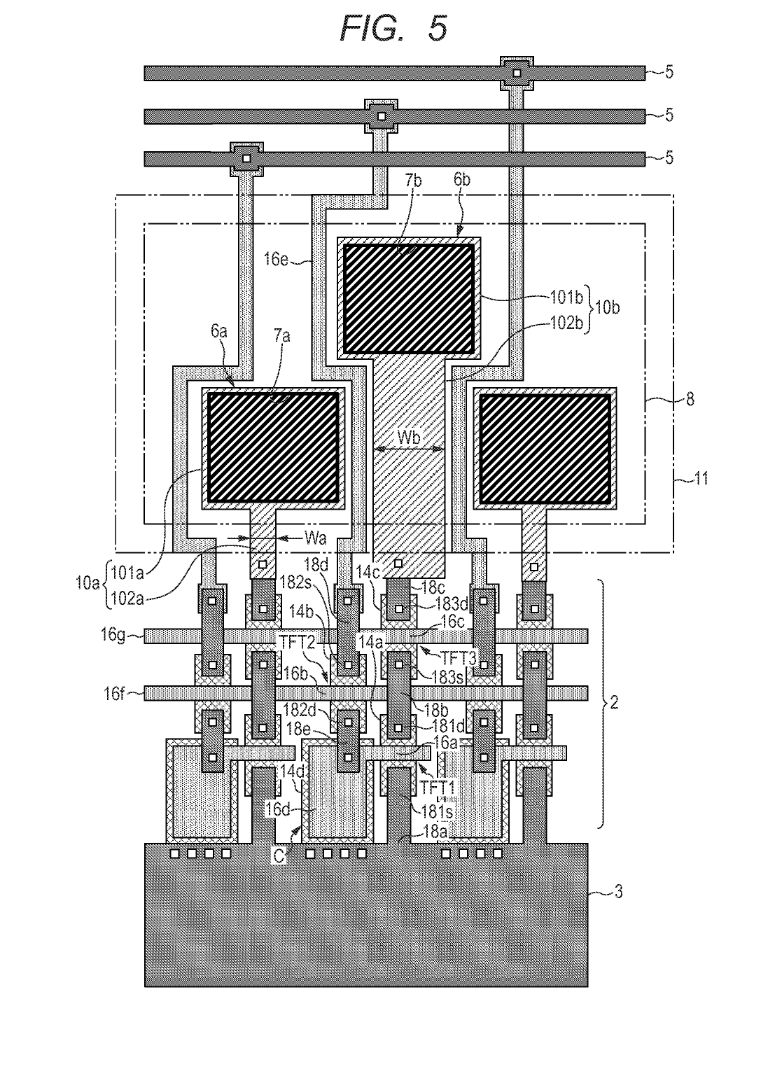

A light emitting apparatus according to a second embodiment of the present invention will be described with reference to FIG. 5. FIG. 5 is a planar view illustrating a configuration of a pixel region and the vicinity of the pixel region in the light emitting apparatus according to the present embodiment. The same constituent elements as in the light emitting apparatus according to the first embodiment are designated with the same reference signs, and the description will be omitted or simplified.

The light emitting apparatus according to the present embodiment is different from the light emitting apparatus according to the first embodiment in that a plurality of pixels 6 (6a and 6b) are arranged in two lines in the longitudinal direction of the substrate 1. In the following description, the pixels 6 of a first line of the two lines of the pixels 6 close to the pixel circuits 2 will be written as “pixels 6a”, and “a” will be attached to ends of reference signs indicating elements related to the pixels 6a as necessary. The pixels 6 of a second line far from the pixel circuits 2 will be written as “pixels 6b”, and “b” will be attached to ends of reference signs indicating elements related to the pixels 6b as necessary.

As illustrated in FIG. 5, the plurality of the pixels 6 is arranged in two lines, the first line and the second line. The first line and the second line include separation regions between the pixels 6, and the pixels 6b included in the second line are arranged at positions equivalent to the separation regions between the pixels 6a in the first line. More specifically, the plurality of the pixels 6a of the first line and the plurality of the pixels 6b of the second line are arranged at the same pitch each other and shifted by half the pitch, in the longitudinal direction of the substrate 1. The arrangement of the pixels 6 can be expressed as a staggered arrangement or a zigzag arrangement. Thus, the plurality of the pixels 6 is arranged in a staggered or zigzag arrangement of two lines in the longitudinal direction of the substrate 1. The staggered arrangement of the pixels 6 can narrow down the pitch of the openings 7 of the pixels 6. As a result, a high-resolution image can be formed when the light emitting apparatus according to the present embodiment is used for an exposure head in an electrophotographic image forming apparatus.

However, the distances from openings 7a and 7b of adjacent pixels 6a and 6b to the pixel circuits 2 are different from each other. More specifically, the distance between the opening 7b of the pixel 6b and the pixel circuit 2 is greater than the distance between the opening 7a of the pixel 6a and the pixel circuit 2. Therefore, if the interconnections are simply laid out, the interconnection resistance from the lower electrode 10 to the pixel circuit 2 connected to the lower electrode 10 varies in each pixel 6, and the light emission luminance varies. More specifically, the interconnection resistance from the lower electrode 10 to the pixel circuit 2 varies between the pixel 6a of the line close to the pixel circuit 2 and the pixel 6b of the line far from the pixel circuit 2, and the light emission luminance varies between the pixels 6a and 6b.

Therefore, a width Wa of an interconnection portion 102a extending from a main body portion 101a of a lower electrode 10a and a width Wb of an interconnection portion 102b extending from a main body portion 101b of a lower electrode 10b are different from each other in the light emitting apparatus according to the present embodiment. More specifically, the width Wb of the interconnection portion 102b of the lower electrode 10b of the pixel 6b corresponding to the opening 7b is greater than the width Wa of the interconnection portion 102a of the lower electrode 10a of the pixel 6a corresponding to the opening 7a. As a result, the interconnection resistance of the interconnection portion 102a and the interconnection resistance of the interconnection portion 102b are the same each other. Thus, the interconnection resistance from the lower electrode 10a to the pixel circuit 2 and the interconnection resistance from the lower electrode 10b to the pixel circuit 2 are the same each other.

The relay interconnection 16e for connecting the data line 5 and the source electrode 182s of the thin film transistor TFT2 is formed to appropriately include bending parts. As a result, the relay interconnection 16e is guided and arranged not to overlap the lower electrodes 10a and 10b as well as the interconnection portions 102a and 102b of the lower electrodes 10a and 10b in planar view from the direction perpendicular to the main surface of the substrate 1.

Thus, an adjustment is made so that the plurality of the pixels 6 has the same interconnection resistance from the lower electrode 10 to the pixel circuit 2 in the light emitting apparatus according to the present embodiment. Therefore, according to the present embodiment, the variations in the voltage drop caused by the interconnection resistance between the plurality of the pixels 6 can be suppressed, and the light emission luminance of the plurality of the pixels 6 can be uniform in the interconnection layout in which relatively thick metal interconnection is not arranged below the organic compound layer 8.

Although the width Wa of the interconnection portion 102a and the width Wb of the interconnection portion 102b are different from each other in the above description, the width Wa of the interconnection portion 102a and the width Wb of the interconnection portion 102b may be the same each other. In this case, the length of the interconnection portion 102a and the length of the interconnection portion 102b are also the same each other, although not illustrated. Since the lengths of the interconnection portions 102a and 102b are the same each other, the pixel circuits 2 corresponding to the pixels 6a and the pixel circuits 2 corresponding to the pixels 6b are arranged in two lines, the first line and the second line, in the longitudinal direction of the substrate 1. The first line and the second line of the pixel circuits 2 have separation regions between the pixel circuits 2. The pixel circuits 2 included in the second line are arranged at positions equivalent to the separation regions in the first line. More specifically, the pixel circuits 2 corresponding to the pixels 6a and the pixel circuits 2 corresponding to the pixels 6b are arranged at the same pitch each other and shifted by half the pitch in the longitudinal direction of the substrate 1. The arrangement of the pixel circuits 2 can be expressed as a staggered arrangement or a zigzag arrangement. Thus, the interconnection portions 102a and 102b can have the same interconnection resistance by arranging the plurality of the pixels 6a and 6b in a staggered manner in the longitudinal direction of the substrate 1 and arranging the pixel circuits 2 corresponding to the pixels 6a and 6b in a staggered manner.

The distances d2 and d3 can be 2 μm or more, wherein d2 is the distance between the part of the metal interconnection 18 closest to the upper electrode 11 and the end of the upper electrode 11, and d3 is the distance between the part of the data line 5 closest to the upper electrode 11 and the end of the upper electrode 11.

### Third Embodiment

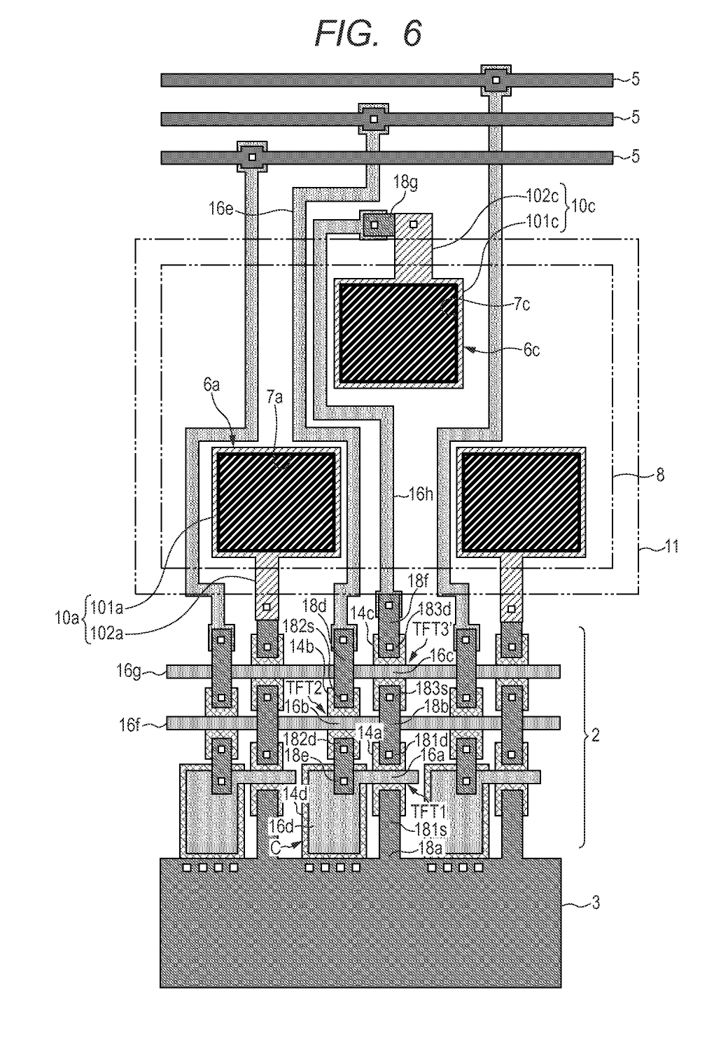

A light emitting apparatus according to a third embodiment of the present invention will be described with reference to FIG. 6. FIG. 6 is a planar view illustrating a configuration of a pixel region and the vicinity of the pixel region in the light emitting apparatus according to the present embodiment. The same constituent elements as in the light emitting apparatuses according to the first and second embodiments are designated with the same reference signs, and the description will be omitted or simplified.

As in the light emitting apparatus according to the second embodiment described above, a plurality of pixels 6 (6a and 6c) are arranged in two lines in the longitudinal direction of the substrate 1 in the light emitting apparatus according to the present embodiment. In the following description, the pixels 6 of the first line of the two lines of the pixels 6 close to the pixel circuits 2 will be written as “pixels 6a”, and “a” will be attached to ends of reference signs indicating elements related to the pixels 6a as necessary. The pixels 6 of the second line far from the pixel circuits 2 will be written as “pixels 6c”, and “c” will be attached to ends of reference signs indicating elements related to the pixels 6c as necessary. In the light emitting apparatus according to the present embodiment, the configuration of the interconnection related to the pixels 6c of the second line far from the pixel circuits 2 is different from that of the light emitting apparatus according to the second embodiment described above.

As illustrated in FIG. 6, the first line and the second line of the pixels 6 have separation regions between the pixels 6, and the pixels 6c included in the second line are arranged at positions equivalent to the separation regions between the pixels 6a in the first line. More specifically, the plurality of the pixels 6a of the first line and the plurality of the pixels 6c of the second line are arranged at the same pitch each other and shifted by half the pitch in the longitudinal direction of the substrate 1. Thus, the plurality of the pixels 6 is arranged in two lines in a staggered or zigzag manner in the longitudinal direction of the substrate 1 as in the configuration illustrated in FIG. 5. On the other hand, the configuration of the interconnection for connecting the pixel circuit 2 and a lower electrode 10c in relation to the pixel 6c in which the distance between the pixel circuit 2 and the lower electrode 10c is large is different from the configuration of the light emitting apparatus according to the second embodiment illustrated in FIG. 5.

In the light emitting apparatus according to the present embodiment, the drain electrode 183d of a thin film transistor TFT3′ corresponding to the thin film transistor TFT3 is integrated with metal interconnection 18f in the pixel circuit 2 corresponding to the pixel 6c. The metal interconnection 18f is made of, for example, aluminum, an aluminum alloy or copper formed of the same layer as the metal interconnection 18a, 18b, 18c, 18d and 18e, the power line 3, and the data lines 5.

The metal interconnection 18f is once connected to relay interconnection 16h through a contact hole. The relay interconnection 16h is made of, for example, aluminum, copper, chromium or an alloy of these formed of the same layer as the gate electrodes 16a, 16b and 16c. The relay interconnection 16h is guided toward the side provided with the data lines 5, between adjacent opening 7a and opening 7c.

In a region between the data lines 5 and the pixel 6c without the formation of the organic compound layer 8, metal interconnection 18g is connected to the relay interconnection 16h through a contact hole.

An interconnection portion 102c of the lower electrode 10c is connected to the metal interconnection 18g through a contact hole. In the lower electrode 10c, the interconnection portion 102c is formed to extend toward the data lines 5 from a main body portion 101c.

The configuration of the interconnection for connecting the pixel circuit 2 and the lower electrode 10a is the same as the configuration of the light emitting apparatus according to the second embodiment described above.

A transparent electrode, such as ITO, is used for the lower electrode 10 as described above when the extraction system of the light emission of the organic EL element OEL is a bottom emission type. However, the sheet resistance of the transparent electrode, such as ITO, is higher than that of the interconnection made of aluminum.

Therefore, the relay interconnection 16h formed of the same layer as the gate electrodes 16a, 16b and 16c is used as part of the interconnection for connecting the lower electrode 10c of the pixel 6c and the pixel circuit 2 in the light emitting apparatus according to the present embodiment. The relay interconnection 16h is made of, for example, aluminum, copper, chromium or an alloy of these, and the sheet resistance of the relay interconnection 16h is lower than that of the transparent electrode such as ITO. According to the present embodiment, using the relay interconnection 16h with a relatively low sheet resistance can reduce the voltage drop caused by the interconnection resistance and can suppress the power consumption of the light emitting apparatus.

The width of the relay interconnection 16h and the width of the interconnection portion 102c extending from the main body portion 101c of the lower electrode 10c are adjusted in the light emitting apparatus according to the present embodiment. As a result, the interconnection resistance of the interconnection portion 102c, the metal interconnection 18g, the relay interconnection 16h and the metal interconnection 18f is the same as the interconnection resistance of the interconnection portion 102a and the metal interconnection 18c. Thus, the interconnection resistance from the lower electrode 10c to the pixel circuit 2 is the same as the interconnection resistance from the lower electrode 10a to the pixel circuit 2.

As described above, the plurality of the pixels 6 is adjusted so that the interconnection resistance from the lower electrodes 10 to the pixel circuits 2 is the same in the light emitting apparatus according to the present embodiment. According to the present embodiment, the variations in the voltage drop caused by the interconnection resistance between the plurality of the pixels 6 can be suppressed, and the light emission luminance of the plurality of the pixels 6 can be uniform in the interconnection layout in which relatively thick metal interconnection is not arranged below the organic compound layer 8.

The distances d2 and d3 can be 2 μm or more, wherein d2 is the distance between the part of the metal interconnection 18 closest to the upper electrode 11 and the end of the upper electrode 11, and d3 is the distance between the part of the data line 5 closest to the upper electrode 11 and the end of the upper electrode 11.

### Fourth Embodiment

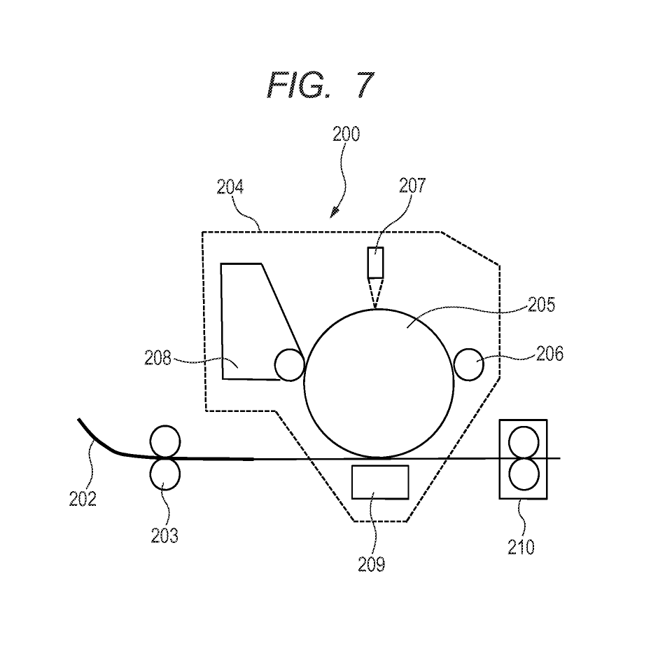

An image forming apparatus according to a fourth embodiment of the present invention will be described with reference to FIG. 7. FIG. 7 is a schematic diagram illustrating the image forming apparatus according to the present embodiment. The same constituent elements as in the light emitting apparatuses according to the first to third embodiments are designated with the same reference signs, and the description will be omitted or simplified. In the image forming apparatus according to the present embodiment, the light emitting apparatus according to one of the first to third embodiments is used for an exposure head.

As illustrated in FIG. 7, an image forming apparatus 200 according to the present embodiment includes a recording unit 204. The recording unit 204 includes a photosensitive drum 205 that is a photoreceptor, a charger 206 that is a charging unit, an exposure head 207 that is an exposure unit, a developing unit 208, and a transfer unit 209. The charger 206, the exposure head 207 and the developing unit 208 are sequentially arranged in a circumferential direction of the photosensitive drum 205. The image forming apparatus 200 also includes conveyor rollers 203 and a fixing unit 210.

The exposure head 207 includes an exposure light source that is the light emitting apparatus according to one of the first to third embodiments, and further includes a drive circuit of the light emitting apparatus. In the exposure head 207, the light emitting apparatus according to one of the first to third embodiments is arranged so that the arrangement direction of the plurality of the pixels 6 arranged in a line is along the rotation axis of the photosensitive drum 205. More specifically, in the exposure head 207, the light emitting apparatus is arranged so that the arrangement direction of the plurality of the pixels 6 is in the major axis direction of the photosensitive drum 205. The light emission of the plurality of the pixels 6 in the light emitting apparatus is controlled according to image data of an image to be formed on paper sheet 202.

In the recording unit 204, the charger 206 uniformly charges the surface of the cylindrical photosensitive drum 205.

The pixels 6 of the light emitting apparatus in the exposure head 207 emits light according to the image data. The photosensitive drum 205 charged by the charger 206 is exposed, and an electrostatic latent image is formed on the photosensitive drum 205. The electrostatic latent image can be controlled by the photosensitive amount (illuminance and time) of the exposure head 207.

In the recording unit 204, the developing unit 208 supplies and attaches toner, which is a developer, to the electrostatic latent image on the photosensitive drum 205. As a result, a toner image is formed on the photosensitive drum 205.

The transfer unit 209 transfers the toner image to the paper sheet 202 conveyed to the recording unit 204 by the conveyor rollers 203. The timing of the conveyance of the paper sheet 202 to the recording unit 204 by the conveyor rollers 203 can be appropriately set.

In this way, the toner image is transferred to the paper sheet 202 based on the image data through the recording unit 204. The paper sheet 202 with the transferred toner image is conveyed to the fixing unit 210.

The fixing unit 210 fixes the toner image on the paper sheet 202 to form the image on the paper sheet 202. The paper sheet 202 provided with the image is discharged to a paper discharge tray.

In this way, the image forming apparatus can be formed by using one of the light emitting apparatuses according to the first to third embodiments as an exposure light source in the exposure head 207.

The plurality of the pixels 6 is arranged in a line in the light emitting apparatuses according to the first to third embodiments, and a configuration of scanning the light from a light source as in the system of scanning the laser light is not necessary. Therefore, according to the present embodiment, the exposure head 207 can be downsized, and as a result, the image forming apparatus can be downsized.

Although an example of a monochrome image forming apparatus with one recording unit 204 is described in the present embodiment, the image forming apparatus is not limited to this. For example, the apparatus may be a color image forming apparatus including a plurality of recording units 204 for the colors of yellow (Y), cyan (C), magenta (M) and black (K).

### Modified Embodiments

The present invention is not limited to the embodiments described above, and various modifications can be made.

For example, the lower electrode 10, the metal interconnection 18c connected to the lower electrode 10, and the drain electrode 183d integrated with the metal interconnection 18c are formed in different layers in the embodiments described above. However, the configuration of the lower electrode 10 and the interconnection connected to the lower electrode 10 is not limited to this.

Although the pixel circuit 2 includes three thin film transistors TFT1, TFT2 and TFT3 and the holding capacitance C in the embodiments described above, the configuration of the pixel circuit 2 is not limited to this. Various configurations can be adopted for the configuration of the pixel circuits 2 as long as the pixel circuits 2 can control the plurality of the pixels 6 to emit light at predetermined timing according to the data signals indicating light emission and non-emission of the pixels 6. The structure and the material of the thin film transistors used in the pixel circuits 2 are not particularly limited. A top-gate structure and a bottom-gate structure can be appropriately used, and various materials can also be used.

Although the source/drain electrodes of the thin film transistors TFT1, TFT2 and TFT3 in the pixel circuits are integrated with the metal interconnection in the examples described in the embodiments, the source/drain electrodes may be formed separately from the metal interconnection.

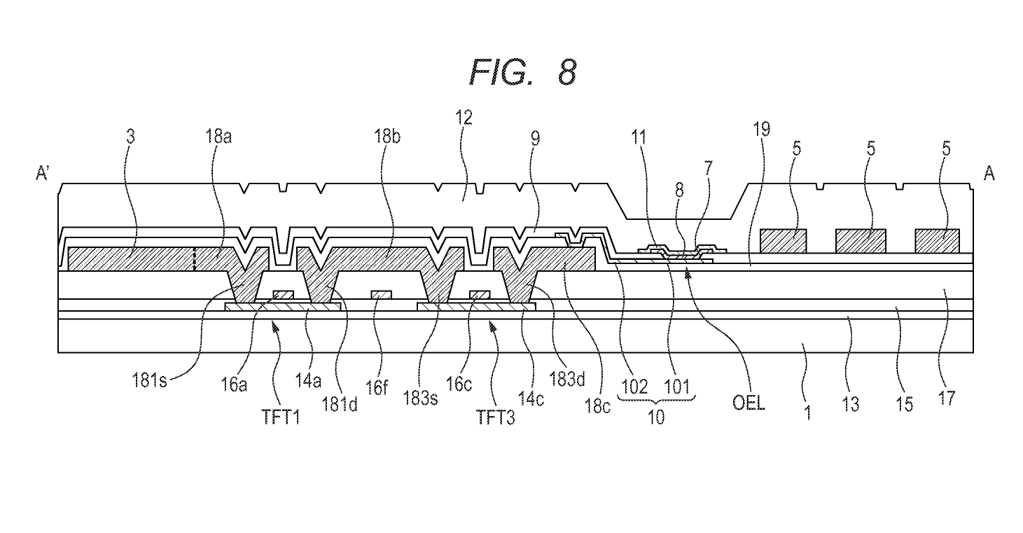

Although the metal interconnection 18 and the data lines 5 are formed of the same layer in the examples described in the embodiments, the metal interconnection 18 and the data lines 5 may be formed of different layers. For example, unlike the metal interconnection 18 formed below the partition layer 9, the data lines 5 may be formed and arranged above the partition layer 9. FIG. 8 is a cross-sectional view illustrating a configuration of a pixel region and the vicinity of the pixel region in a light emitting apparatus according to a modified embodiment in which the data lines 5 are arranged above the partition layer 9.

As illustrated in FIG. 8, the metal interconnection 18 including the metal interconnection 18a, 18b, and 18c and the power line 3 is formed on the interlayer insulating layer 17. The passivation layer 19 is formed on the interlayer insulating layer 17 provided with the metal interconnection 18. The organic EL element OEL is formed as in the embodiments described above. The partition layer 9 is formed on the passivation layer 19.

The plurality of the data lines 5 is formed on the partition layer 9. The sealing film 12 is formed on the upper electrode 11 of the organic EL element OEL and on the partition layer 9 provided with the plurality of the data lines 5. As described, the data lines 5 and the metal interconnection 18 may be formed of different layers, and the data lines 5 may be arranged on the partition layer 9.

### EXAMPLES

Although effects of the present invention will be described along with examples, the present invention is not limited to these.

Here, light emitting apparatuses are manufactured, in which the distance from the metal interconnection 18 and the data lines 5 to the end of the upper electrode 11 is changed. Environmental tests of 1000 hours at a temperature of 85° C. and a humidity of 85% for 1000 hours are conducted for the light emitting apparatuses, and a relationship between degrees of degradation of the organic EL elements OEL is illustrated. The light emitting apparatuses including the array of the organic EL elements described in the first embodiment illustrated in FIGS. 2 to are manufactured as samples for conducting the environmental tests. The materials and the thicknesses of the layers in the manufactured light emitting apparatus are as follows. The material of the first control line 16f including the gate electrode 16b, the second control line 16g including the gate electrode 16c, and the relay interconnection 16h is aluminum, and the film thickness is 0.15 μm. The material of the metal interconnection 18 is aluminum, and the film thickness is 0.9 μm. The material of the passivation layer 19 is silicon nitride, and the film thickness is 0.2 μm. The material of the lower electrode 10 is ITO, and the film thickness is 0.08 μm. The material of the partition layer 9 is silicon nitride, and the film thickness is 0.2 μm. The organic compound layer 8 has a layered structured using the following organic materials, and the film thickness is 0.148 μm.

The compounds used to manufacture the organic compound layer 8 are illustrated below.

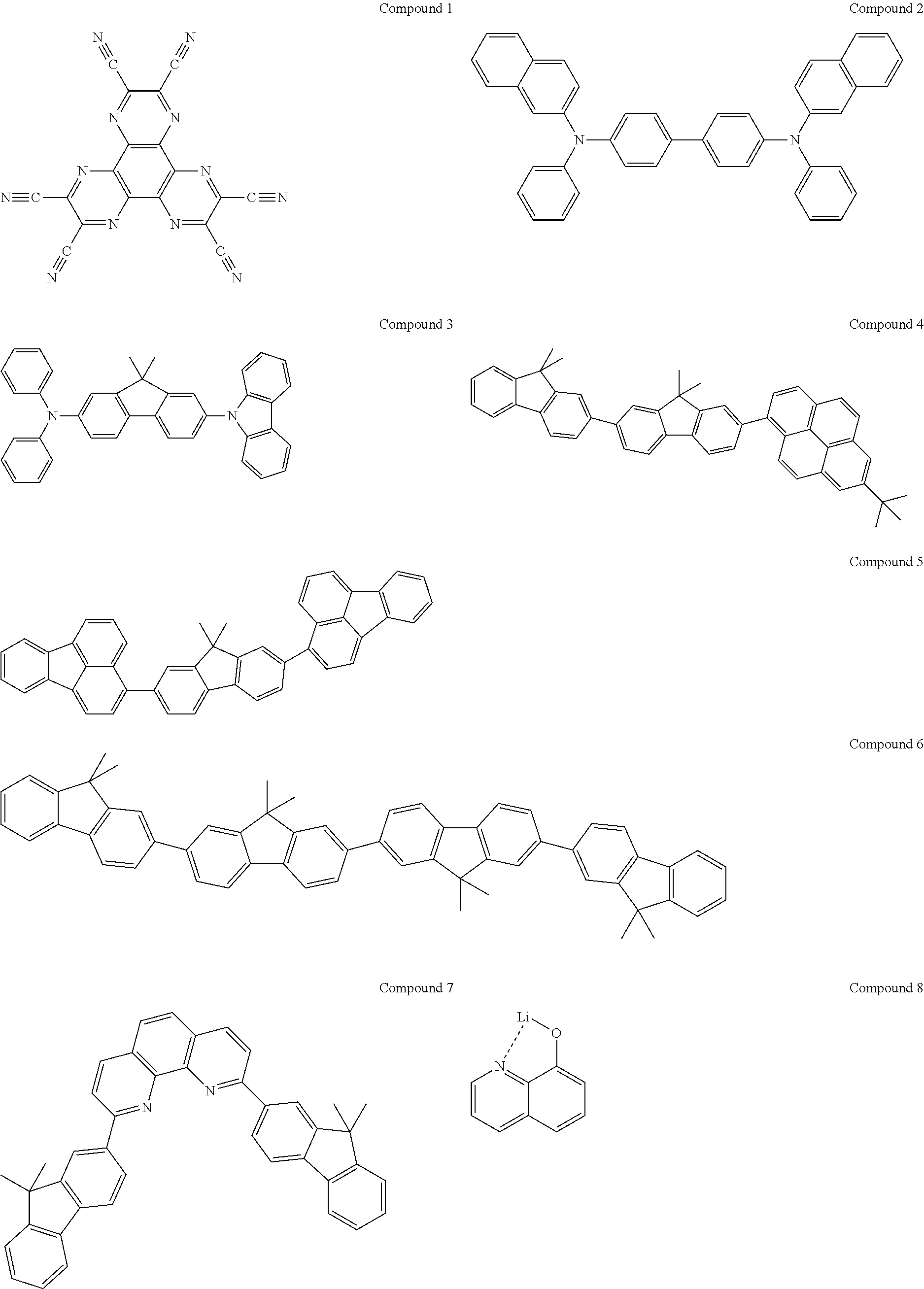

Compound 1 is deposited on the lower electrode 10 as a hole injection layer with a film thickness of 3 nm. Compound 2 is deposited as a hole transport layer with a film thickness of 50 nm. Compound 3 is deposited as an electron block layer with a film thickness of 10 nm. Compound 4 as a host and Compound 5 as a light emitting material are codeposited so that Compound 4 contains 1 volume % of Compound 5, to form a light emitting layer with a film thickness of 20 nm. Compound 6 is deposited as a hole block layer with a film thickness of 10 nm, and Compound 7 is deposited as an electron transport layer with a film thickness of 40 nm. Compound 8 and Compound 7 are codeposited so that 30 volume % of Compound 8 is included with respect to Compound 7, to form an electron injection layer with a film thickness of 15 nm.

The material of the upper electrode 11 is aluminum, and the film thickness is 0.2 μm. The material of the sealing film 12 is silicon nitride, and the film thickness is 2.0 μm. The passivation layer 19, the partition layer 9 and the sealing film 12 are formed by the CVD method. The first control line 16f including the gate electrode 16b, the second control line 16g including the gate electrode 16c, the relay interconnection 16h, the metal interconnection 18, and the lower electrode 10 are formed by the sputtering method. The organic compound layer 8 and the upper electrode 11 are formed by the vacuum deposition method. In the present examples, the film thickness of the metal interconnection 18 and the film thickness of the data lines 5 are equal. The distance d2 between the metal interconnection 18 and the upper electrode 11 and the distance d3 between the data lines 5 and the upper electrode 11 are equal, and they will be collectively written as distance d.

Table 1 illustrates light emitting areas after the environmental tests of samples in Reference Examples 1 to 3 and Examples 1 to 3 with different distances d. The light emitting area illustrated in Table 1 is indicated by a ratio (%) of a measured value of the light emitting area measured after the environmental test to a design value of the light emitting area. As can be understood from Table 1, the reduction in the light emitting area tends to decrease with an increase in the distance d from the metal interconnection 18 (and the data lines 5) to the end of the upper electrode 11. As a result of the environmental tests, the light emitting area is reduced in Reference Examples 1, 2 and 3 in which the distance d is smaller than 2.0 μm. The reduction of the light emitting area is generated from the side of the metal interconnection 18 and the data lines 5, and the reduction is caused by infiltration of external water and oxygen. On the other hand, the light emitting area is maintained after the environmental tests in Examples 1, 2 and 3 in which the distance d is 2.0 μm or more. Therefore, it can be understood that the organic EL elements OEL can be protected from water and oxygen entered form the outside if the distance d is at least 2 μm or more.

TABLE 1

| | | Light Emitting |
|---|---|---|
| | Distance d [μm] | Area [%] |
| Reference Example 1 | 0.5 | 10 |
| Reference Example 2 | 1.0 | 55 |
| Reference Example 3 | 1.5 | 90 |
| Example 1 | 2.0 | 100 |
| Example 2 | 5.0 | 100 |
| Example 3 | 50 | 100 |

According to the embodiments of the present invention, excellent sealing performance can be realized, and light emission performance of the light emitting element can be maintained for a long time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefits of Japanese Patent Application No. 2014-163708, filed Aug. 11, 2014, and Japanese Patent Application No. 2015-090355, filed Apr. 27, 2015, which are hereby incorporated by reference herein in their entirety.

What is claimed is:

1. A light emitting apparatus comprising:
a pixel circuit formed over a long substrate;
a partition formed over the substrate provided with the pixel circuit, the partition including a plurality of openings; and
a plurality of pixels defined by the plurality of the openings, wherein
the pixel comprises a light emitting element comprising a lower electrode connected to the pixel circuit and an organic compound layer formed over the lower electrode,
the plurality of the pixels is arranged in a line in a longitudinal direction of the substrate,
the pixel circuit comprises: a transistor comprising a gate electrode and source/drain electrodes; a first interconnection comprising the gate electrode; and a second interconnection comprising the source/drain electrodes, and
the second interconnection and an interconnection formed of a same layer as the second interconnection are separated from the organic compound layer in planar view from a direction perpendicular to a main surface of the substrate.

2. The light emitting apparatus according to claim 1, further comprising
at least one of a third interconnection formed of a same layer as the first interconnection and a fourth interconnection formed of a same layer as the lower electrode, the third interconnection and the fourth interconnection formed between the substrate and the organic compound layer.

3. The light emitting apparatus according to claim 1, wherein
the partition is made of an inorganic material.

4. The light emitting apparatus according to claim 1, wherein
the plurality of the pixels is arranged in a single line.

5. The light emitting apparatus according to claim 1, wherein
the plurality of the pixels is arranged in two lines, a first line and a second line,
the first line and the second line include separation regions between the pixels, and
the pixels included in the second line are arranged at positions equivalent to the separation regions in the first line.

6. The light emitting apparatus according to claim 5, wherein
an interconnection resistance from the lower electrode of the pixel arranged in the first line to the pixel circuit and an interconnection resistance from the lower electrode of the pixel arranged in the second line to the pixel circuit are the same each other.

7. The light emitting apparatus according to claim 6, wherein
a distance from the pixel arranged in the first line to the pixel circuit is longer than a distance from the pixel arranged in the second line to the pixel circuit, and
a width of an interconnection portion connecting the lower electrode of the pixel arranged in the first line and the pixel circuit is greater than a width of an interconnection portion connecting the lower electrode of the pixel arranged in the second line and the pixel circuit.

8. The light emitting apparatus according to claim 6, further comprising
a fifth interconnection for connecting the lower electrode of the pixel arranged in the first line and the pixel circuit, the fifth interconnection formed of a same layer as the first interconnection.

9. A light emitting apparatus comprising:
a pixel circuit formed over a long substrate;
a partition formed over the substrate provided with the pixel circuit, the partition made of an inorganic material including a plurality of openings; and
a plurality of pixels defined by the partition,
the pixel comprising a light emitting element comprising: a lower electrode connected to the pixel circuit; an upper electrode; and an organic compound layer arranged between the lower electrode and the upper electrode,
a part of the upper electrode arranged on the partition, a data line for supplying a signal arranged adjacent to the upper electrode, wherein
a distance between an end of the upper electrode and the data line in an in-plane direction is 2 μm or more.

10. The light emitting apparatus according to claim 1, wherein
the organic compound layer is formed in a band shape in the longitudinal direction of the substrate and is common to the light emitting elements in the plurality of the pixels.

11. The light emitting apparatus according to claim 9, wherein
the organic compound layer is formed in a band shape in the longitudinal direction of the substrate and is common to the light emitting elements in the plurality of the pixels.

12. An image forming apparatus comprising:
a photoreceptor;
a charging unit configured to charge the photoreceptor;
an exposure unit configured to expose the photoreceptor, the exposure unit comprising the light emitting apparatus according to claim 1; and
a developing unit configured to supply a developer to the photoreceptor, wherein
the plurality of the pixels included in the light emitting apparatus is arranged in a major axis direction of the photoreceptor.

13. An image forming apparatus comprising:
a photoreceptor;
a charging unit configured to charge the photoreceptor;
an exposure unit configured to expose the photoreceptor, the exposure unit comprising the light emitting apparatus according to claim 1; and
a developing unit configured to supply a developer to the photoreceptor, wherein
the plurality of the pixels included in the light emitting apparatus is arranged in a major axis direction of the photoreceptor.
